(19) United States
(12) Patent Application Publication
(10) Pub. No.: US 2025/0016914 A1
(43) Pub. Date: Jan. 9, 2025

(54) FLEXIBLE PRINTED CIRCUIT BOARD

(71) Applicant: SONNENSEE GMBH, Wien (AT)

(72) Inventors: Oleksii IVANOV, Odessa (UA); Semen VARTANOV, Wien (AT)

(21) Appl. No.: 18/711,285

(22) PCT Filed: Dec. 7, 2022
(86) PCT No.: PCT/EP2022/084740

§ 371 Date: May 17, 2024

(30) Foreign Application Priority Data
Dec. 22, 2021 (EP) 21217156.5

(51) Int. Cl. H05K 1/02; H05K 1/03

(52) U.S. Cl. CPC H05K 1/0281; H05K 1/0393; H05K 2201/057

(57) ABSTRACT

The developed construction of the flexible circuit board is distinguished by the presence of compensating folds with a simple topology, which allow the circuit board to be installed in a flexible-hard body in such a way that the integrity of the circuit board is maintained when bending and rolling up, and the lifespan of the device during rolling/unrolling reaches 100,000 cycles and more.

The invention relates to a bendable electronic component according to claim 1 and solves the problem of increasing the flexibility of electronic printed circuit boards and the products based on them.

US 2014/0018166 A1 discloses an attachment that is worn on the palm side or the back of the metacarpal bone of a person's hand. The attachment includes a flexible band or strip to which an electronic sensor module is attached, which contains electronics for detecting gesture features performed by the wearer's hand, including a communication interface for transmitting gesture feature data to a system outside the hand attachment. The attachment sends position and orientation data in real-time when a gesture is performed to an external system, e.g., a gaming terminal. Optional sensors for detecting light, acceleration, orientation, or pressure can be used to capture other gesture features and/or user inputs made while wearing the attachment. The gestures and user inputs can be used to influence graphical objects displayed on one or more displays that represent a program, e.g., a betting game.

WO 2015/038684 A1 reveals an attachable article or device, such as a bracelet, which includes a flexible electronic display arranged in a shape that is bendable or conforms to the user's wrist or another curved surface, and allows various images to be displayed on the display, which is bendable or conforms to the wrist or another curved surface of the user. The attachable item implements a notification routine that enables a user or wearer to receive notifications about incoming messages and selectively view incoming messages or indications thereof.

US 2017/0168523 A1 relates to a wearable computing device that is configured to be comfortably worn around the user's wrist. In some aspects, the wearable computing device may have a bistable housing that is configured to be mechanically stable in. Flexible electronic devices are becoming more accessible and current thanks to the development of electronics and the production of modern elastic materials. For wearable electronics, which in most cases are represented by flexible devices, e.g., foldable and bendable smartphones, fitness bands, smartwatches, etc., a particularly current issue is the flexibility and elasticity of the printed circuit board.

Two approaches are used for the production of flexible or flexibly-elastic electronic printed circuit boards: by applying special geometry and topology of the printed circuit board at the folding points themselves or by utilizing flexible and elastic conductive materials. In the first case, the printed circuit board or its part can be executed, for example, in a meander shape [1], which can achieve a degree of flexibility and even elasticity. This approach is widely used because it is not expensive and simple in manufacturing and production. However, it has some disadvantages: the special geometry and topology of the printed circuit board are generally space-consuming and have a limited lifespan when bending.

In the second case, the printed circuit board is created from materials with conductivity [2] that are complex in their properties, which ensure the minimum possible dimensions of the product alongside flexibility and elasticity. A major disadvantage of this approach is the high cost of elastic conductive materials.

The current situation highlights the relevance of developing solutions for flexible printed circuit boards with a high lifespan when bending and using simple technologies and materials.

The inventive bendable electronic component is characterized by the following features: A flexible printed circuit board, comprising end sides each at least in a longitudinal and a width direction of the printed circuit board, and a flexible substrate to which the printed circuit board is fixed with two of its opposing end sides. According to the invention, it is provided that the printed circuit board has at least one fold or gather parallel to the end sides, which is formed as a raised bend from the substrate.

In principle, the longitudinal direction and the width direction can be dimensioned to be the same or similar in length. Other geometric shapes of the flexible printed circuit board are also conceivable, which do not allow sharp distinctions between a longitudinal and a width direction, such as a circular shape. It may be expedient that the end sides fixed to the substrate are approximately opposite each other. An end side can also be referred to as an edge area or as opposing edge areas. The end sides can be referred to as a fixed contact area of the flexible printed circuit board against the substrate. The end sides can extend beyond an edge area of the printed circuit board and describe a flat edge-near area or section.

According to a preferred development of the invention, it can be provided that the material of the flexible printed circuit board adjacent to and/or, in particular at the fold or gather, is free from fixations against the substrate.

A practical development of the invention may consist in that the flexible printed circuit board has at least in the fold or gather a simple, bendable topology.

Preferably, it can be provided that the substrate is a modified bistable spring with at least two bistable spring devices and two plates connecting them flatly at the ends.

Conveniently, it can be provided that above the fold, a, preferably limited, free space is provided, which serves as an expansion area for the fold. Instead of a free space, a displaceable material, such as foam, can also be provided.

However, the free space above the fold is optional, as an enlarging fold or gather during a bend of the flexible printed circuit board can also bend inward (into itself), whereby instead of an enlarging U-shape, as shown in FIG. 1b, an M- or W-shape can also form in the area of the fold. In principle, the fold or gather itself already forms the requisite free space into which additional fold- or gather-forming material can expand during a bend of the flexible printed circuit board.

### In the Drawings:

FIG. 1 Flexible printed circuit board: 1—electronic printed circuit board, 2—flexible non-elastic substrate, 3—adhesive, 4—fold, 5—body and

FIG. 2 The printed circuit board in a bendable-hard body with modified bistable spring: 1-13 the printed circuit board, 5—the body, 6—the spring

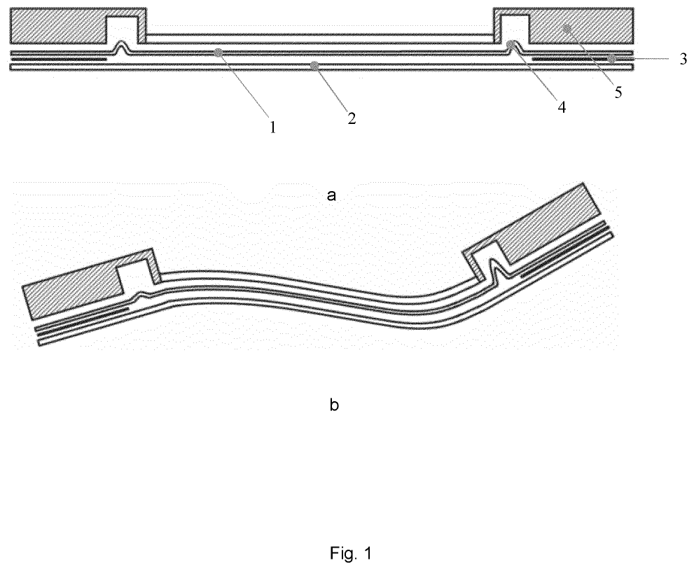

The essence of the invention may consist in that a bendable, but not elastic printed circuit board 1 is attached to a bendable non-elastic substrate 2, for example by means of adhesive 3, which is applied, for example, at the ends of the printed circuit board edges, forming at least one compensating fold 4, as shown in FIG. 1a. The fold forms a uniform, preferentially local, bend of the printed circuit board and can have the shape, for example, of half the period of the sine function.

The fold can, for example, be held by a bendable body, especially in a provided receptacle or depression, as shown in FIG. 1. As a printed circuit board, for example, a multilayer printed circuit board based on polyamide, as an adhesive/bonding agent double-sided tape, and as a body polycarbonate or elastomer can serve.

When the whole construction bends or unfolds, the fold 4 can accordingly straighten/smooth out or fold more/increase its bend, as shown in FIG. 1b. This compensates for the displacement of the printed circuit board 1 relative to the substrate 2 during bending or rolling up.

The dimensions of the compensating fold 4 can, for example, be determined based on the circuit board tolerance—that is, the minimum permissible bending radius of the circuit board and the number of bends. The minimum dimension of the fold, which allows for greater flexibility and the number of bending cycles of the whole construction, is possible for the single-layer structure of the circuit board in the fold area.

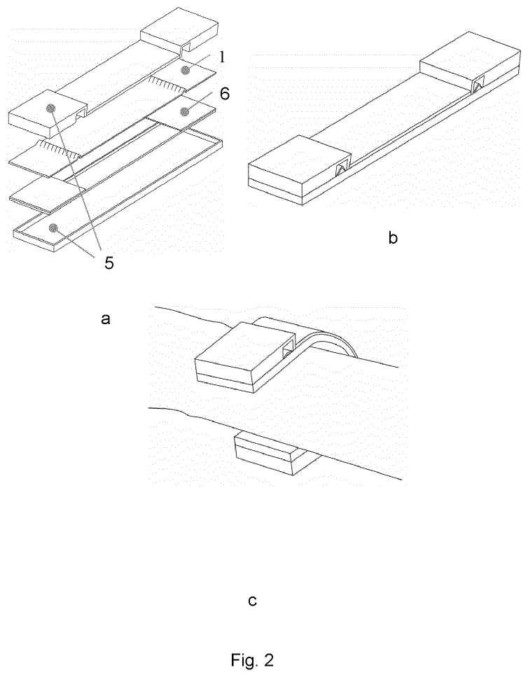

Furthermore, such a circuit board construction can be accommodated in a body 5 with flexible and hard parts, as shown in FIGS. 2a and 2b.

When bending and rolling up the body, the circuit board with compensating folds retains its integrity and can function fully.

Such a circuit board can be mounted on a modified bistable spring 6, as shown in FIG. 2 and described in EP 21 173 821.6. The modified bistable spring can serve as a substrate 2 or be part of the substrate 2. The modified bistable spring consists of a series of parallel bistable springs that are connected flatly at their ends by hard/stiff plates; the circuit board 1 can be attached to the spring with an adhesive, for example, tape, preferentially over the whole surface, with the exception of the compensating folds, which in turn lie freely over the hard plates of the modified bistable spring. The resulting construction can be installed in the flexible-hard body 5, resulting in a wearable device in the form of a bracelet with built-in electronics. Such a bracelet represents a wearable electronic device that, thanks to the rolling up of the bistable spring, can be worn on the wrist, for example, and, thanks to the ability to unroll and maintain a flat position due to the bistable springs, can be removed.

Thanks to the developed construction of the flexible circuit board, such a device achieves as a technical result the increase in reliability and lifespan of the built-in electronics alongside the use of simple technologies and materials. Among other things, the lifespan of the product can reach 100,000 cycles and more.
1. Flexible Circuit Board (Meander) [Flexible PCB and FPCB assembly | Hitech Circuits Co., Ltd.] (https://hitechcircuits.com/flexible-pcb/) (https://hitechcircuits.com/flexible-pcb/)
2. Elastic Circuit Board [Panasonic develops flexible and resilient circuit boards for electronics Science. Daily Techinfo & Technology News, Tech News.] (https://dailytechinfo.org/electronics/7691-kompaniya-panasonic-sozdala-gibkie-i-elastichnye-pechatnye-platy-diya-elektroniki.html) ( )

1. Bendable electronic component with a flexible circuit board (1), comprising end sides each at least in a longitudinal and a width direction of the circuit board (1), and a flexible substrate (2), to which the circuit board (1) is fixed with two of its opposing end sides characterized by
that the circuit board (1) has at least one fold (4) or gather parallel to the end sides, which is formed as a raised bend from the substrate (2).

2. Bendable electronic component according to claim 1, characterized by that the material of the flexible circuit board (1) adjacent to and/or, in particular at the fold (4) or gather, is free from fixations against the substrate (2).

3. Bendable electronic component according to claim 1, characterized by
that the flexible circuit board (1) has at least in the fold (4) or gather a simple, bendable topology.

4. Bendable electronic component according to claim 1 characterized by
that the substrate (2) is or comprises a modified bistable spring with at least two bista-ble spring devices and two plates connecting them flatly at their end sides.
